(19) United States
(12) Patent Application Publication
(10) Pub. No.: US 2015/0208530 A1
(43) Pub. Date: Jul. 23, 2015

(54) SECURING STRUCTURE OF ELECTRICAL PERIPHERAL DEVICE

(71) Applicant: AIC INC., Taoyuan Hsien (TW)

(72) Inventors: Lin-Kuei TSAI, Taoyuan Hsien (TW); Chung-I KUO, Taoyuan Hsien (TW)

(73) Assignee: AIC INC., Taoyuan Hsien (TW)

(21) Appl. No.: 14/160,824

(22) Filed: Jan. 22, 2014

(51) Int. Cl. H05K 5/02

(52) U.S. Cl. CPC H05K 5/0221

(57) ABSTRACT

The present invention relates to a securing structure (10) of an electrical peripheral device (100) having a positioning plate (101). The securing structure (10) includes a fastening seat (1) and a sliding seat (2) connected to and sliding on the fastening seat (1). One end of the sliding seat (2) has a detent part (21) which is able to press and lock the top of the positioning plate (101) correspondingly. Thus, the installation and uninstallation of the electrical peripheral device (100) are made efficient and the convenience of using the securing structure is improved.

### BACKGROUND OF THE INVENTION

1. Field of the Invention

The present invention relates to a securing structure of an electrical peripheral device and, in particular, to a securing structure for fixing an electrical peripheral device such as a power supply or a hard disk drive.

2. Description of Related Art

With substantial development of the computer technology, the design, manufacturing, and assembly of computer equipment advance accordingly. To allow the vendor or customer to change, repair, or upgrade the electrical peripheral device such as the power supply or the hard disk drive by himself/herself, the electrical peripheral device is usually fixed to the supporting frame of the computer equipment using screws. Thus, the vendor or customer can install/uninstall the electrical peripheral device in/from the supporting frame.

A traditional method of securing the electrical peripheral device to the supporting frame by screws is as follows. Firstly, the vendor or customer prepares some screws and matched hand tools; the screws are then placed, one by one, through the respective holes of the electrical peripheral device and the supporting frame using the hand tools to drive the screws. Thus, the screws and the holes are combined firmly and the electrical peripheral device is fixed to the supporting frame well.

However, the above method has the following disadvantages. First, the hand tools are required for the installation and uninstallation of the electrical peripheral device by attaching or detaching the screws one by one. Therefore, the additional requirement of matched tools and the tedious process are inconvenient for the vendor or customer, and retard the processes of installation and uninstallation. Second, after the screws are detached, a single screw is not easy to keep and easy to miss due to its small volume, failing to continue the following installation process.

In view of this, the inventor pays special attention to research with the application of related theory and tries to overcome the above disadvantages regarding the above related art, which becomes the goal of the inventor's improvement.

### SUMMARY OF THE INVENTION

The present invention is to provide a securing structure of an electrical peripheral device, which uses a sliding seat to control a detent part to lock or be detached from a positioning plate correspondingly. Thus, the installation and uninstallation of the electrical peripheral device are made efficient and the convenience of using the securing structure is improved.

The present invention provides a securing structure of an electrical peripheral device having a positioning plate. The securing structure comprises:

a fastening seat; and

a sliding seat connected to and sliding on the fastening seat, one end of the sliding seat having a detent part which is able to press and lock the top of the positioning plate correspondingly.

The present invention has the following effects.

First, the juts, ribs, or bulges of the fastening seat can prevent the positioning plate from swaying from side to side. In addition, the detent part can press and lock the top of the positioning plate, preventing the electrical peripheral device from swaying up and down. Thus, the electrical peripheral device can be fixed more firmly with the securing structure.

Second, when the sliding seat is sliding, it can move the detent part to press and lock or be detached from the positioning plate correspondingly. The quick installation/uninstallation of the electrical peripheral device in/from the securing structure is thus achieved. The assembly and disassembly by the vendor or customer are made more efficient.

Third, during the process of installing/uninstalling the electrical peripheral device in/from the securing structure, no auxiliary tools and disassembly devices are required. Thus, there are no issues of tedious installation/uninstallation processes and easily losing the screws, providing improved convenience of using the securing structure for the vendor or customer.

Fourth, the securing structure further comprise a locking switch through which the sliding seat and the fastening seat can be positioned to each other such that the sliding seat is locked by the locking switch and cannot move, which forces the detent part to keep pressing and locking the positioning plate and prevents the positioning plate from being detached from the detent part when swayed or impacted, such that the electrical peripheral device is fixed firmly with the securing structure.

### BRIEF DESCRIPTION OF DRAWING

FIG. 1 is a perspective and exploded view of a securing structure according to the first embodiment of the present invention;

FIG. 2 is another perspective and exploded view of a securing structure according to the first embodiment of the present invention;

FIG. 3 is a schematic view of a securing structure in an operational state according to the first embodiment of the present invention;

FIG. 4 is a schematic view of a securing structure in another operational state according to the first embodiment of the present invention;

FIG. 5 is a perspective and exploded view of a securing structure according to the second embodiment of the present invention;

FIG. 6 is another perspective and exploded view of a securing structure according to the second embodiment of the present invention;

FIG. 7 is a schematic view of a securing structure in an operational state according to the second embodiment of the present invention;

FIG. 8 is a schematic view of a securing structure in another operational state according to the second embodiment of the present invention;

FIG. 9 is a schematic view of a securing structure in yet another operational state according to the second embodiment of the present invention;

FIG. 10 is a schematic view of a securing structure in still another operational state according to the second embodiment of the present invention;

FIG. 11 is a perspective and exploded view of a securing structure according to the third embodiment of the present invention;

FIG. 12 is another perspective exploded view of a securing structure according to the third embodiment of the present invention;

FIG. 13 is a schematic view of a securing structure in an operational state according to the third embodiment of the present invention;

FIG. 14 is a schematic view of a securing structure in another operational state according to the third embodiment of the present invention;

FIG. 15 is a perspective and exploded view of a securing structure according to the fourth embodiment of the present invention;

FIG. 16 is another perspective and exploded view of a securing structure according to the fourth embodiment of the present invention;

FIG. 17 is a schematic view of a securing structure in an operational state according to the fourth embodiment of the present invention; and

FIG. 18 is a schematic view of a securing structure in another operational state according to the fourth embodiment of the present invention.

### DETAILED DESCRIPTION OF THE INVENTION

The detailed description and technical contents regarding the present invention are explained as follows, accompanied with the attached figures. However, the attached figures are only used for reference and explanation, not to limit the present invention.

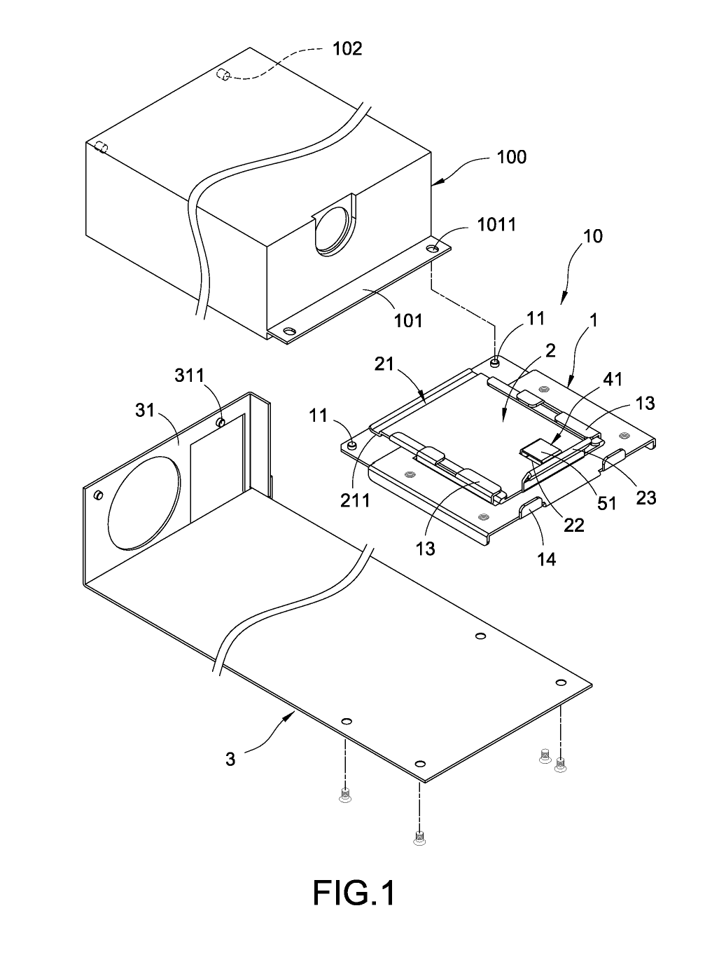

Please refer to FIGS. 1-4, which show the securing structure according to the first embodiment of the present invention. The present invention provides a securing structure of an electrical peripheral device. The securing structure 10 comprises a fastening seat 1 and a sliding seat 2.

As shown in FIG. 1, the electrical peripheral device 100 may be an apparatus such as a power supply or a hard disk drive. In the current embodiment, the electrical peripheral device 100 is preferably a power supply, but not limited to this. The positioning plate 101 is disposed at one end of the electrical peripheral device 100. A plurality of locking holes 102 are disposed at the other end of the electrical peripheral device 100. The positioning plate 101 is provided with a plurality of through holes 1011.

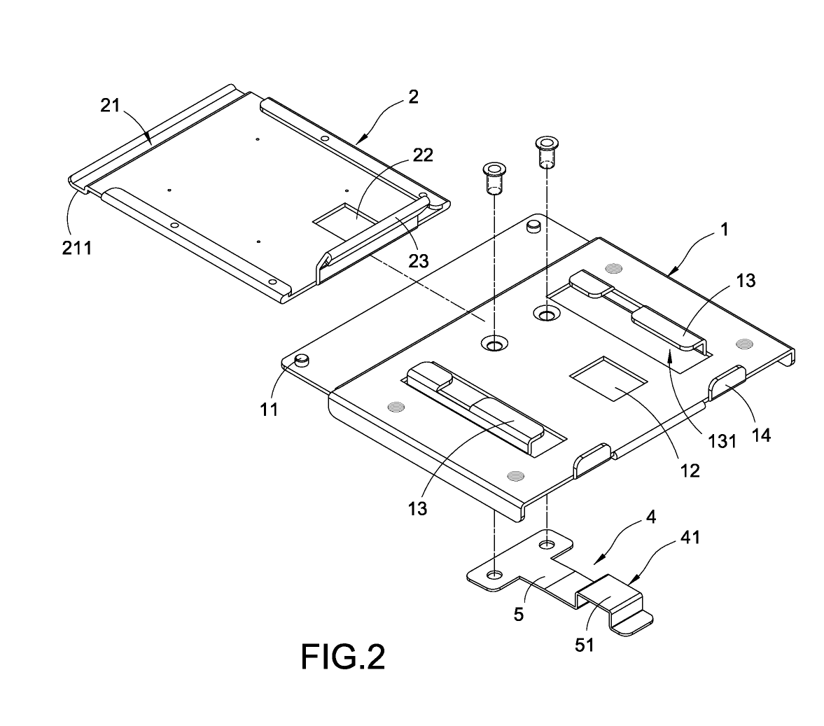

As shown in FIGS. 1 and 2, the fastening seat 1 has a plurality of juts 11. The through holes 1011 are engaged with the corresponding juts 11 such that one end of the electrical peripheral device 100 is fixed to the securing structure 10 correspondingly. Besides, the fastening seat 1 is provided with an opening 12. Two L-shaped walls 13 extend from the opposite sides of the fastening seat 1. A track 131 is formed between the two L-shaped walls 13. At least one stopping tab 14 extends from the fastening seat 1.

As shown in FIGS. 1 and 2, the sliding seat 2 is connected to and slides on the fastening seat 1. A detent part 21 is disposed at one end of the sliding seat 2. The detent part 21 is able to press and lock the top of the positioning plate 101 correspondingly.

Also, the detent part 21 is a U-shaped portion 211 extending from the sliding seat 2 toward the positioning plate 101 such that the U-shaped portion 211 protrudes from the sliding seat 2 to definitely press and lock the top of the positioning plate 101 correspondingly. The detent part 21 may have a straight, U-shaped, or L-shaped cross section, but not limited to that in the current embodiment.

In addition, two sides of the sliding seat 2 are received in the two L-shaped walls 13, respectively, and the sliding seat 2 can slide with respect to the fastening seat 1 by means of the track 131. The stopping tab 14 is formed at one end, away from the detent part 21, of the fastening seat 1 such that the stopping tab 14 can withstand the sliding seat 2 to limit the movement range of the sliding seat 2.

Also, a toggle plate 23 extends from one end, away from the detent part 21, of the sliding seat 2, allowing the vendor or customer to move the sliding seat 2 by means of the toggle plate 23 to slide with respect to the fastening seat 1.

As shown in FIGS. 1 and 2, the securing structure 10 of the present invention further comprises a supporting frame 3, one end of which extends to form a stopping plate 31 and the opposite end of which is for securing the fastening seat 1 such that the electrical peripheral device 100 is clamped between the stopping plate 31 and the detent part 21. The further explanation is given below.

The stopping plate 31 has a plurality of projecting pegs 311. Each of the projecting pegs 311 is engaged with the corresponding locking hole 102 such that the other end of the electrical peripheral device 100 is fixed to the stopping plate 31 correspondingly.

Some corresponding holes are provided on the fastening seat 1 and the supporting frame 3. The fastening seat 1 is fixed firmly to the supporting frame 3 using screws through the corresponding holes. Thus, the fastening seat 1 can be installed in/uninstalled from the supporting frame 3.

As shown in FIGS. 1 and 2, the securing structure 10 of the present invention further comprises a locking switch 4 through which the sliding seat 2 and the fastening seat 1 can be positioned to each other to keep the detent part 21 on the top of the positioning plate 101. The detailed explanation is given below.

The locking switch 4 is connected to the fastening seat 1 and has an engaged portion 41. The sliding seat 2 is provided with an engaged hole 22 which can be engaged with the engaged portion 41.

Besides, the locking switch 4 is an elastic arm 5 fixed to the fastening seat 1. The engaged portion 41 is a bent protrusion 51 bent from the elastic arm 5. The bent protrusion 51 is exposed to the opening 12 and can be engaged with the engaged hole 22 correspondingly. The elastic arm 5 is fixed to the fastening seat 1 by riveting, but not limited to this.

The assembly of the securing structure 10 of the present invention is as follows. The sliding seat 2 is connected to and slides on the fastening seat 1. A detent part 21 is disposed at one end of the sliding seat 2. The detent part 21 is able to press and lock the top of the positioning plate 101. Thus, the sliding seat 2 can control a detent part 21 to press and lock or be detached from a positioning plate 101 correspondingly. The installation and uninstallation of the electrical peripheral device 100 are made efficient and the convenience of using the securing structure is improved.

Also, the securing structure 10 further comprises a supporting frame 3. One end of the supporting frame 3 extends to form a stopping plate 31 and the opposite end of the supporting frame 3 is for securing the fastening seat 1. The stopping plate 31 has a plurality of projecting pegs 311 which are engaged with the corresponding locking holes 102 such that the electrical peripheral device 100 is clamped between the stopping plate 31 and the detent part 21, improving the stable fixation between the electrical peripheral device 100 and the securing structure 10.

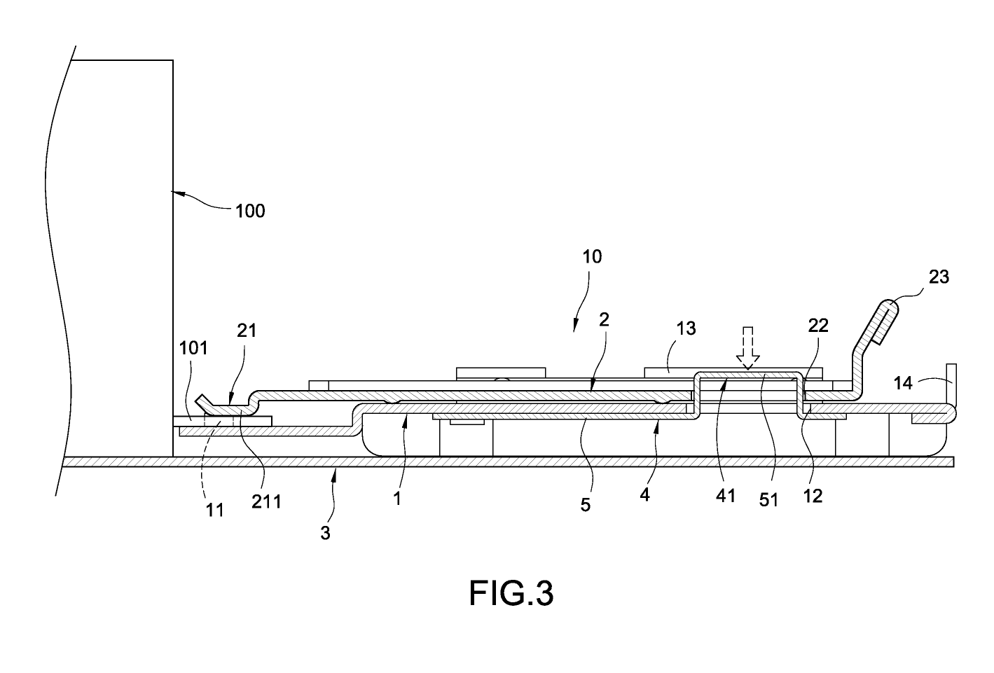

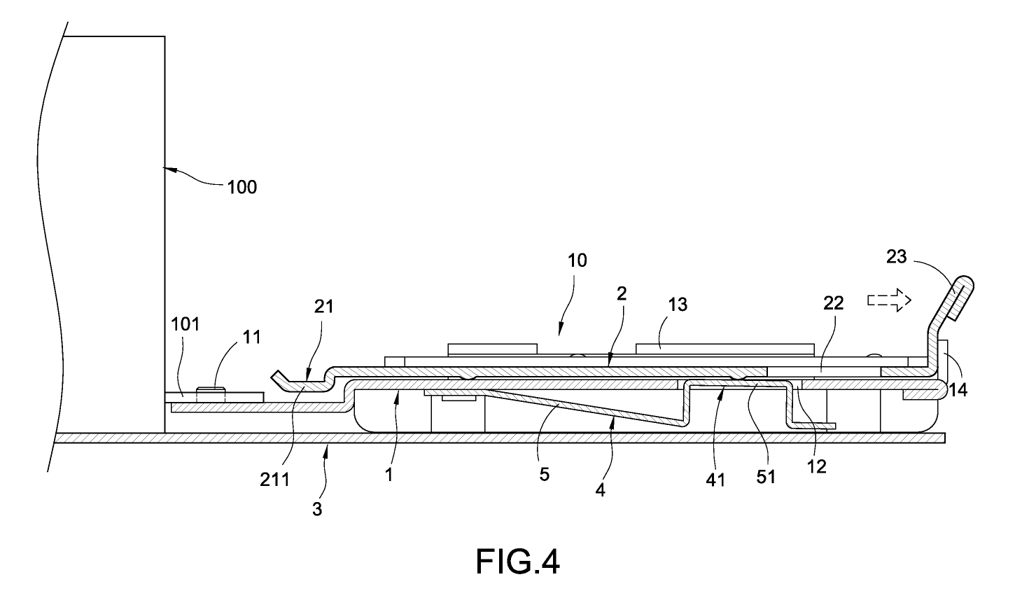

FIG. 3 is a schematic view showing an operational state of the securing structure 10 of the present invention. The locking holes 102 at one end of the electrical peripheral device 100 are engaged with the corresponding projecting pegs 311; the other end of the electrical peripheral device 100 is pressed to be positioned by the detent part 21 such that the electrical peripheral device 100 is clamped between the stopping plate 31 and the detent part 21. As shown in FIG. 4, the sliding seat 2 slides away from the electrical peripheral device 100 and moves the detent part 21 to be detached from the positioning plate 101. Then, the electrical peripheral device 100 can be uninstalled from the securing structure 10.

In the current embodiment, the juts 11 of the fastening seat 1 are engaged with the corresponding through holes 1011 of the positioning plate 101, preventing the electrical peripheral device 100 from swaying from side to side. Also, the detent part 21 presses and locks the top of the top of the positioning plate 101 correspondingly to prevent the electrical peripheral device 100 from sway up and down, which enables the electrical peripheral device 100 to be fixed more firmly to the securing structure 10.

Moreover, when the sliding seat 2 is sliding, it can move the detent part 21 to press and lock or be detached from the positioning plate 101 correspondingly. The quick installation/uninstallation of the electrical peripheral device 100 in/from the securing structure is thus achieved. The assembly and disassembly by the vendor or customer are thus made more efficient.

In addition, the traditional electrical peripheral device is fixed to the supporting frame using hand tools and screws; however, during the process of installing/uninstalling the electrical peripheral device 100 in/from the securing structure 10 of the present invention, no auxiliary tools and disassembly devices are required. Thus, there are not issues of tedious installation/uninstallation processes and easily losing the screws, providing improved convenience of using the securing structure for the vendor or customer.

The securing structure 10 of the present invention further comprises the locking switch 4 through which the sliding seat 2 and the fastening seat 1 can be positioned to each other such that the sliding seat 2 is locked by the locking switch 4 and cannot move, which forces the detent part 21 to keep pressing and locking the positioning plate 101 and prevents the positioning plate 101 from being detached from the detent part 21 when swayed or impacted such that the electrical peripheral device 100 is fixed firmly to the securing structure. The further explanation is given below.

The bent protrusion 51 is exposed to the opening 12 and can be engaged with the engaged hole 22 correspondingly; thus, the sliding seat 2 is locked by the locking switch 4 and cannot move, which forces the detent part 21 to keep pressing and locking the positioning plate 101. When the bent protrusion 51 is pressed to be detached from the engaged hole 22, the sliding seat 2 can slide and move the detent part 21 to be detached from the positioning plate 101 correspondingly.

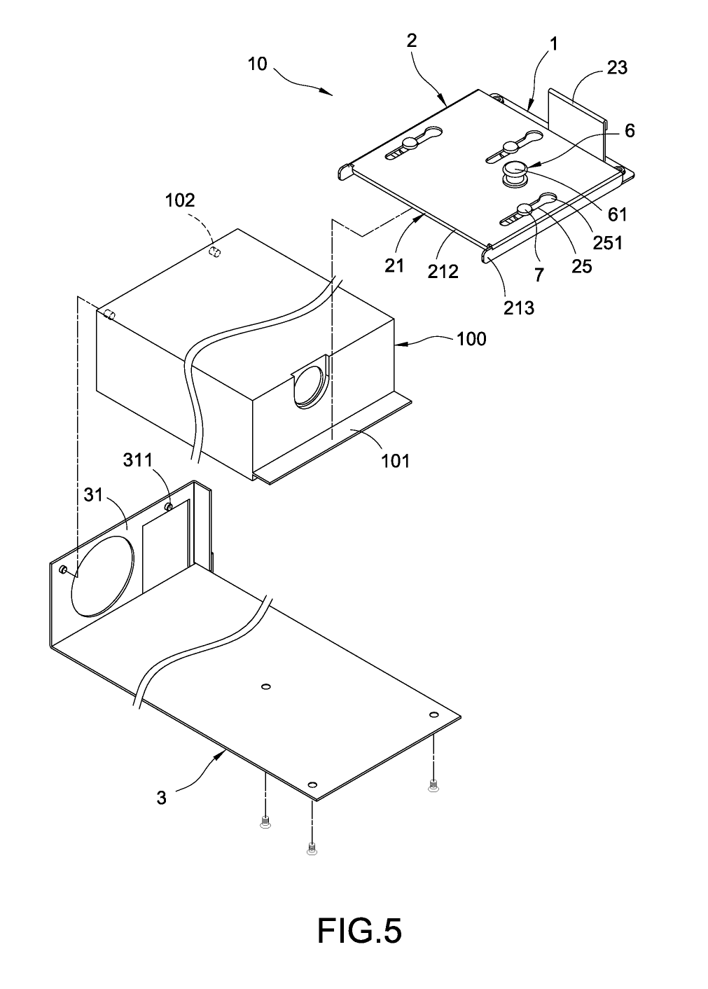

Please refer to FIGS. 5-10, which show the securing structure according to the second embodiment of the present invention. The second embodiment is basically similar to the first embodiment. They differ in the sliding mechanism of the sliding seat 2 and the locking switch 4 associated with the fastening seat 1.

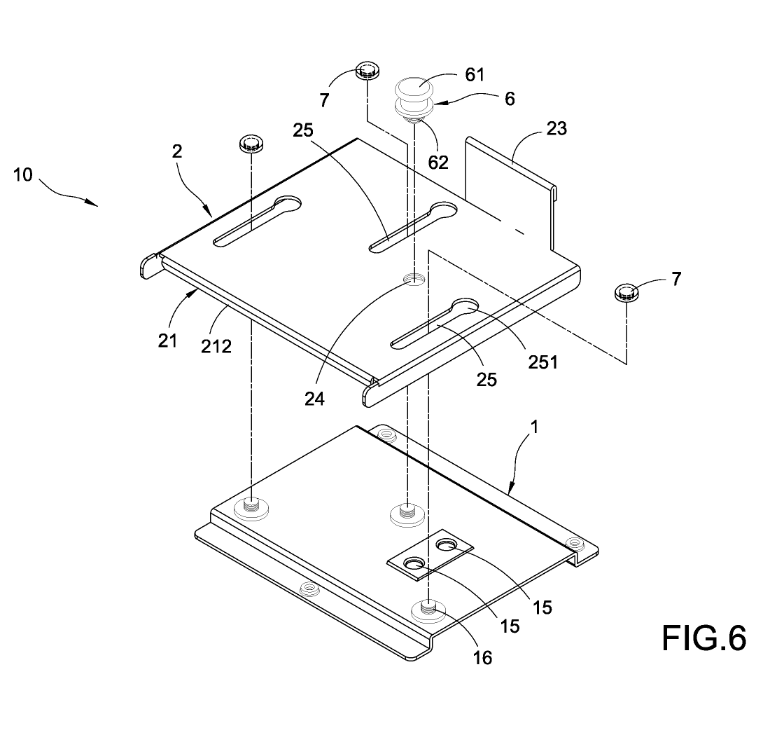

As shown in FIGS. 5 and 6, the detailed structure of the locking switch 4 is detailed below. The locking switch 4 is connected to the sliding seat 2 and has an engaged portion 41. The fastening seat 1 is provided with an aperture 15 with which the engaged portion 41 is engaged correspondingly.

In the current embodiment, there are plural apertures 15. The sliding seat 2 is provided with an orifice 24. The locking switch 4 is an elastic clasp 6 fixed to the sliding seat 2. The elastic clasp 6 comprises a knob 61, a connecting rod 62, and a spring 63 connected between the knob 61 and the connecting rod 62. The engaged portion 41 is formed at the end of the connecting rod 62.

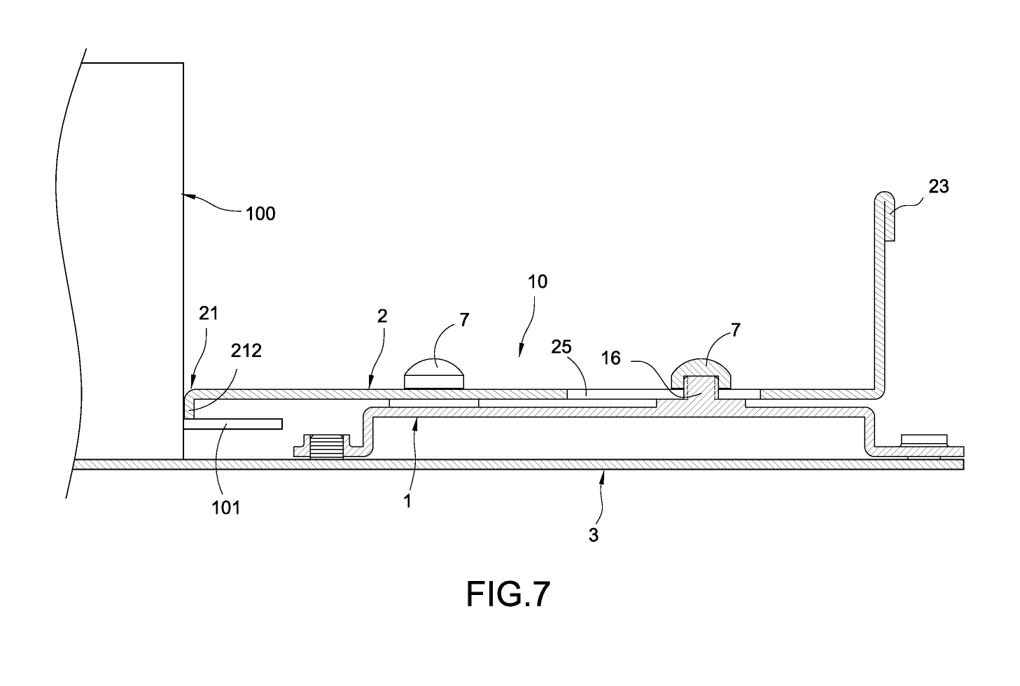

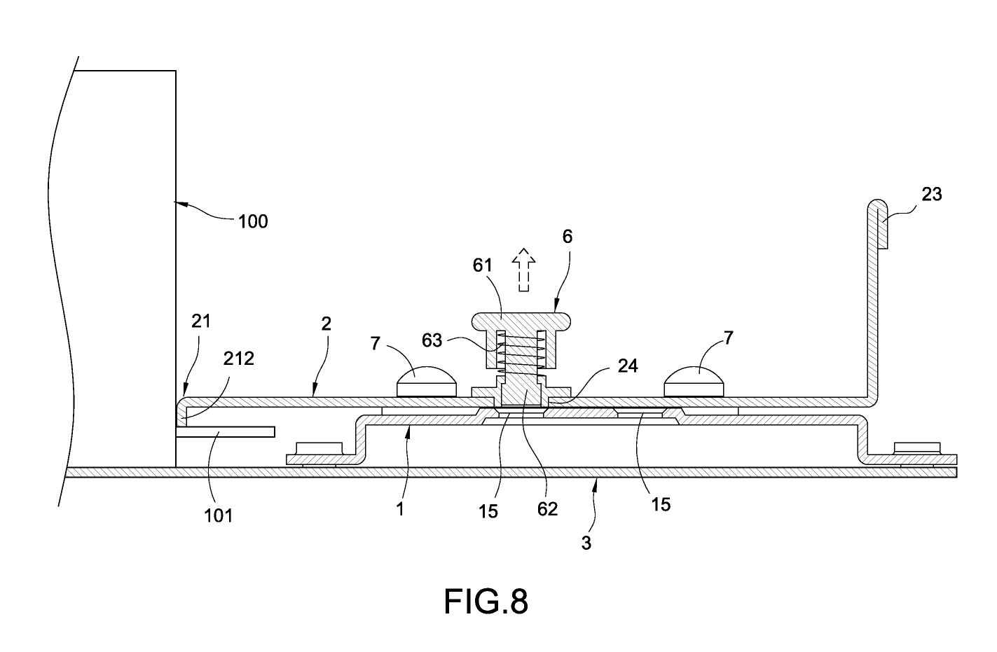

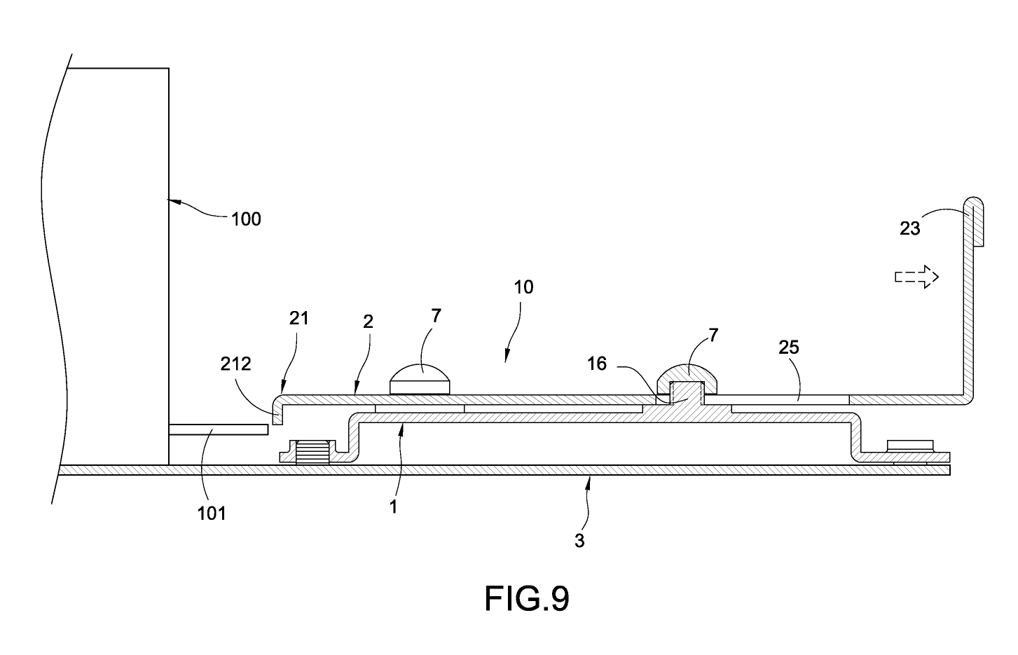

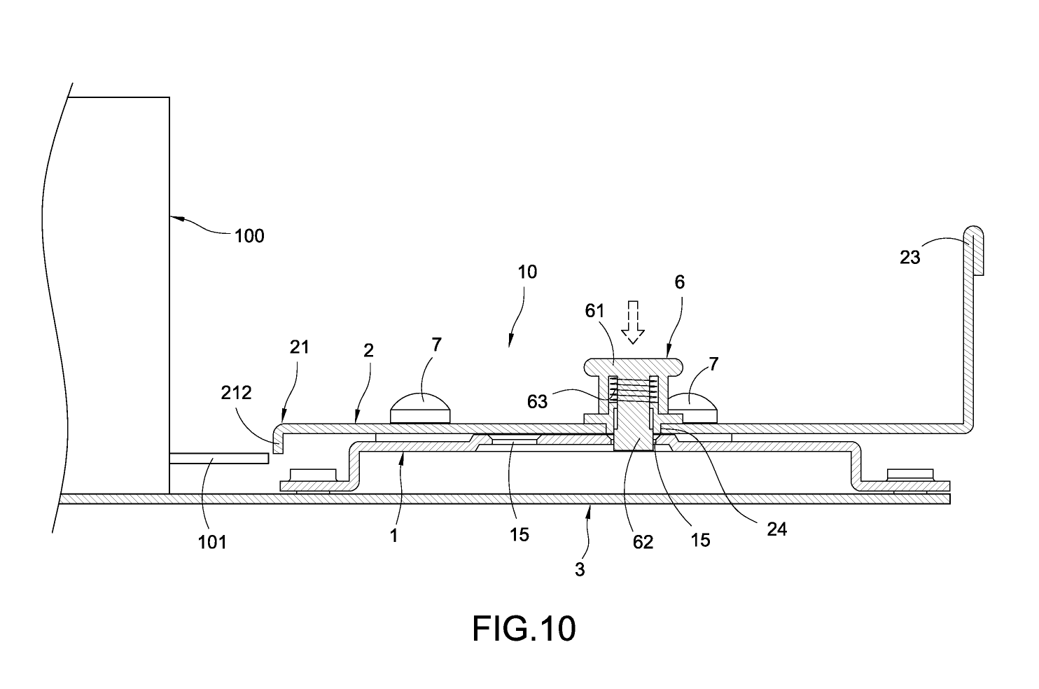

When the knob 61 is released, the spring 63 will automatically push against the connecting rod 62 to approach the aperture 15 such that the connecting rod 62 passes through the orifice 24 to be engaged with the aperture 15 adjacent to the positioning plate 101, causing the sliding seat 2 to be locked by the locking switch 4 and not to move, which forces the detent part 21 to keep pressing and locking the positioning plate 101. As shown in FIGS. 7 and 8, when the knob 61 is pulled up, it will move the connecting rod 62 by means of the spring 63 to be de disengaged from the aperture 15. As a result, the sliding seat 2 can slide and move the detent part 21 away from the positioning plate 101. As shown in FIGS. 9 and 10, when the knob 61 is pushed down, the spring 63 will automatically push against the connecting rod 62 to approach the aperture 15 such that the connecting rod 62 passes through the orifice 24 to be engaged with the aperture 15 away from the positioning plate 101, causing the detent part 21 to keep detached from the positioning plate 101. In this way, the second embodiment achieves the same function and effect as the first embodiment.

As shown in FIGS. 5-10, the sliding structure of the sliding seat 2 associated with the fastening seat 1 is described below in details. The securing structure 10 of the present invention further comprises a plurality of screw nuts 7. The fastening seat 1 has a plurality of screw bolts 16. The sliding seat 2 has a plurality of track slots 25. Each of the screw bolts 16 penetrates through the corresponding track slots 25 to be screwed to the corresponding screw nuts 7 such that the sliding seat 2 is clamped between the screw bolts 16 and the screw nuts 7, whereby the sliding seat 2 can slide with respect to the fastening seat 1 by means of the track slots 25. In this way, the second embodiment achieves the same function and effect as the first embodiment.

In the current embodiment, an enlarged hole 251 is disposed at one end of each of the track slots 25. The circumferential size of the enlarged hole 251 is larger than that of the screw nut 7 so as to facilitate assembly/disassembly of the sliding seat 2 with/from the fastening seat 1, improving the convenience of using the securing structure.

In addition, a combination of various locking switches 4 and various sliding structures of the sliding seat 2 associated with the fastening seat 1 can be used in any embodiment of the present invention. For example, the locking switch 4 in the first embodiment can be used with the sliding structure of the sliding seat 2 associated with the fastening seat 1 in the second embodiment.

Besides, the detent part 21 is an L-shaped portion 212 extending from the sliding seat 2 toward the positioning plate 101. The detent part 21 may have a straight, U-shaped, or L-shaped cross section.

In the second embodiment, two ribs 213 extend on two ends of the detent part 21 and the two ribs 213 can be allocated to two ends of the positioning plate 101 to stop the positioning plate 101. Compared with the first embodiment shown in FIG. 1, the ribs 213 in the second embodiment have the same function as the juts 11 in the first embodiment. Either the ribs 213 or the juts 11 can be used in any embodiment of the present invention, depending on the requirement.

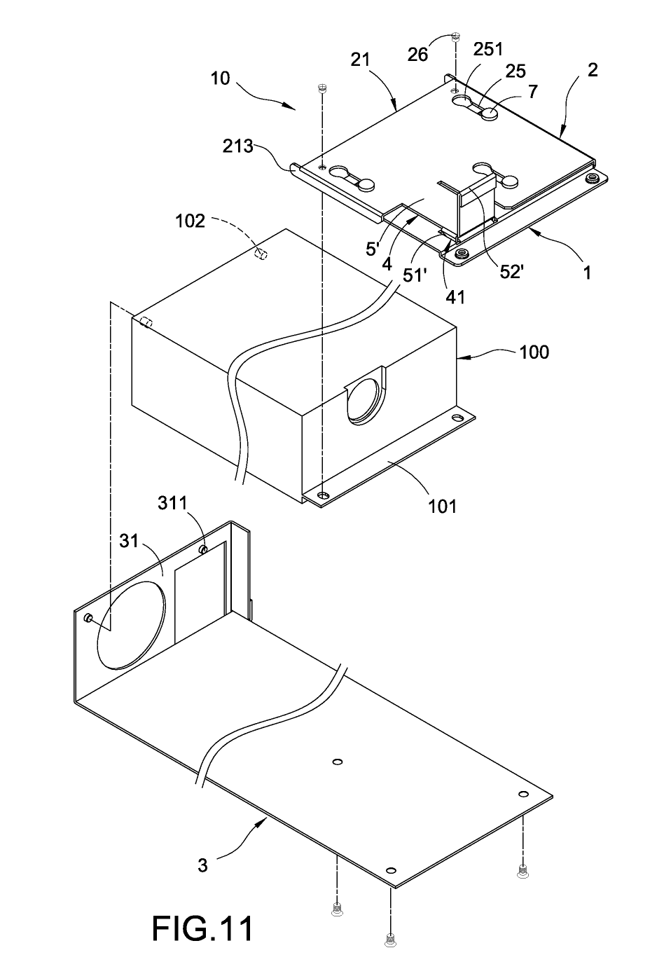

Please refer to FIGS. 11-14, which show the third embodiment of the present invention. The third embodiment is basically similar to the second embodiment. They differ in the structure of the locking switch 4. The detailed description is given below.

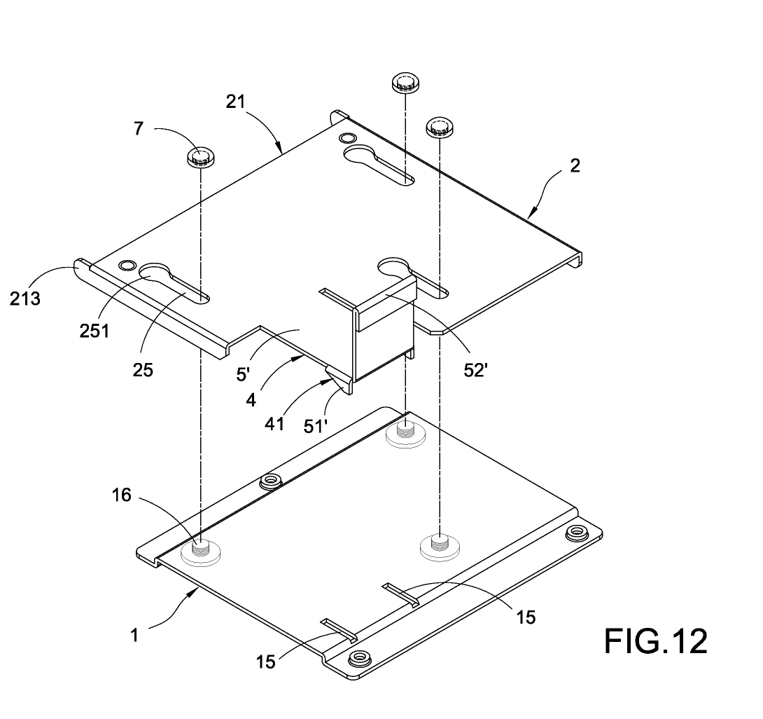

As shown in FIGS. 11 and 12, there are two apertures 15. The locking switch 4 is an elastic arm 5′ extending from the sliding seat 2. The engaged portion 41 is composed of two bent protrusions 51′ respectively bent at two sides of the elastic arm 5′. The two bent protrusions 51′ can be engaged with the two apertures 15 correspondingly. A toggle piece 52′ extends from one end, away from the detent part 21, of the elastic arm 5′, allowing the vendor or customer to move the sliding seat 2 by means of the toggle piece 52′ to slide with respect to the fastening seat 1.

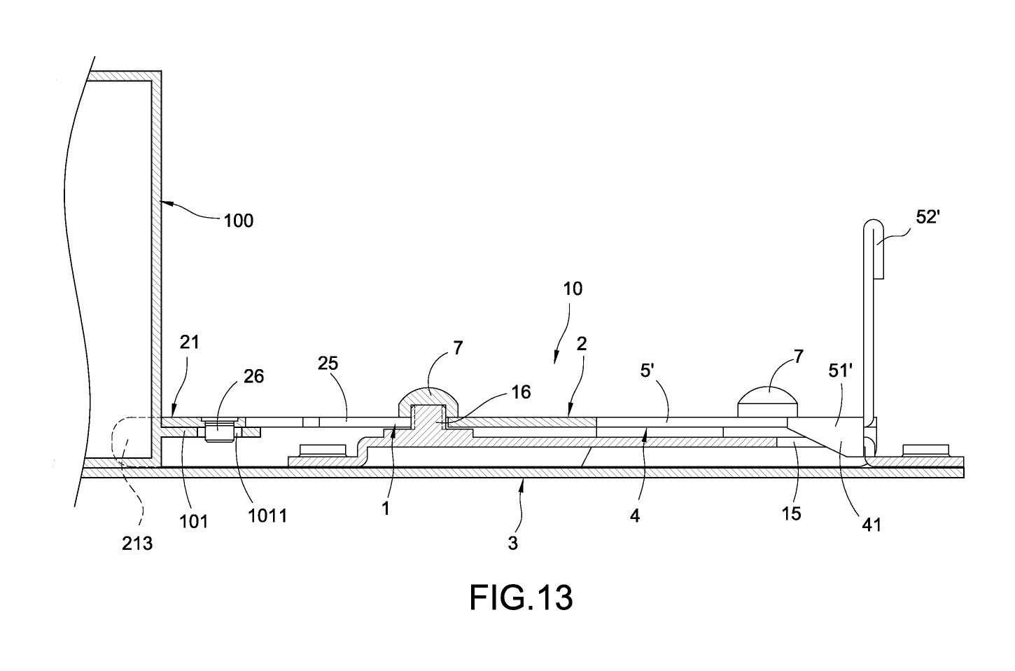

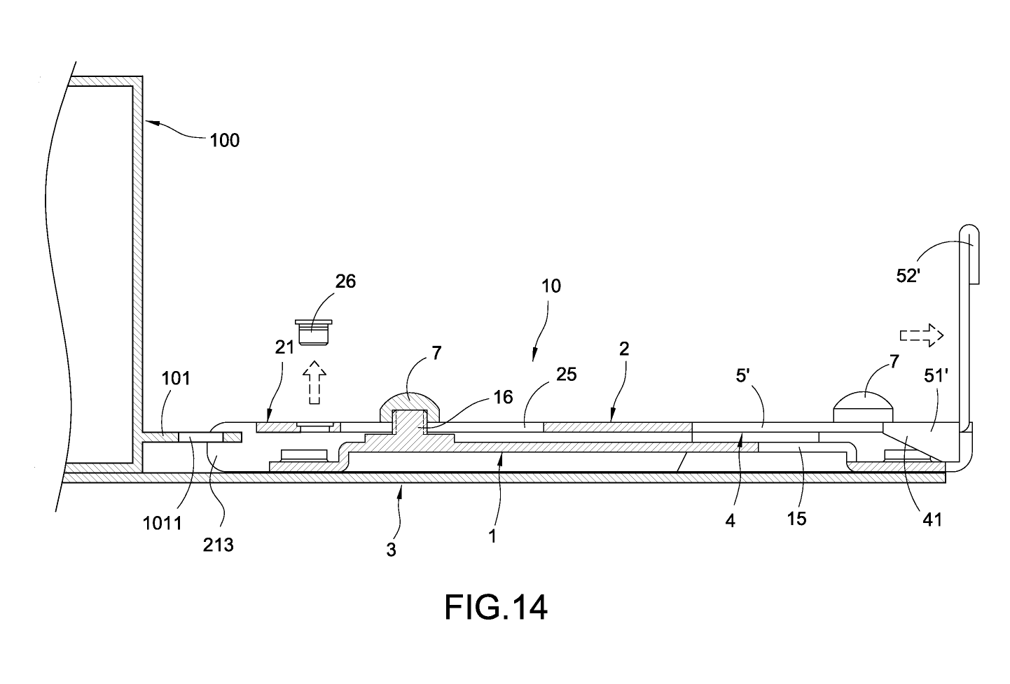

As shown in FIG. 13, when two bent protrusions 51′ are engaged with two apertures 15 correspondingly, the sliding seat 2 is locked by the locking switch 4 and cannot move, forcing the detent part 21 to keep pressing and locking the positioning plate 101. As shown in FIG. 14, when the elastic arm 5′ is pulled up, it will move the bent protrusions 51′ to be disengaged from the apertures 15. As a result, the sliding seat 2 can slide and move the detent part 21 away from the positioning plate 101. In this way, the third embodiment achieves the same function and effect as the second embodiment.

Besides, locking switches 4 of various structures can be used in any embodiment of the present invention, depending on the requirement.

Also, the sliding seat 2 has a plurality of bulges 26. The positioning plate 101 is provided with a plurality of through holes 1011 engaged with the corresponding bulges 26. Compared with the second embodiment shown in FIG. 5, the bulges 26 in the third embodiment have the same function as the ribs 213 in the second embodiment. Either bulges 26 or the ribs 213 can be used in any embodiment of the present invention, depending on the requirement.

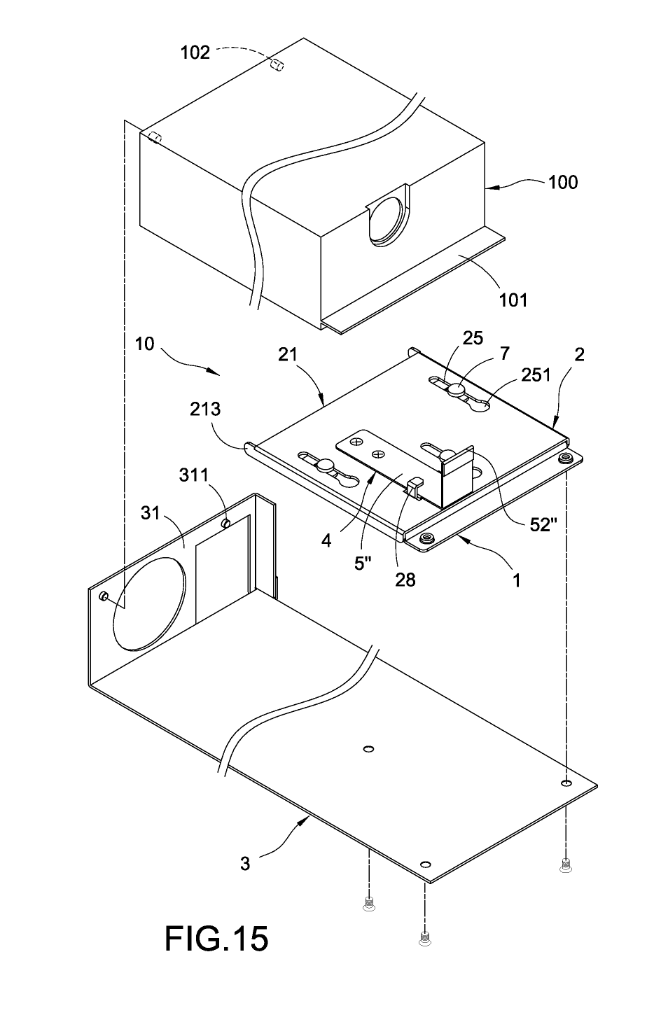

Please refer to FIGS. 15-18, which show the fourth embodiment of the present invention. The fourth embodiment is basically similar to the second embodiment. They differ in the structure of the locking switch 4. The detailed description is given below.

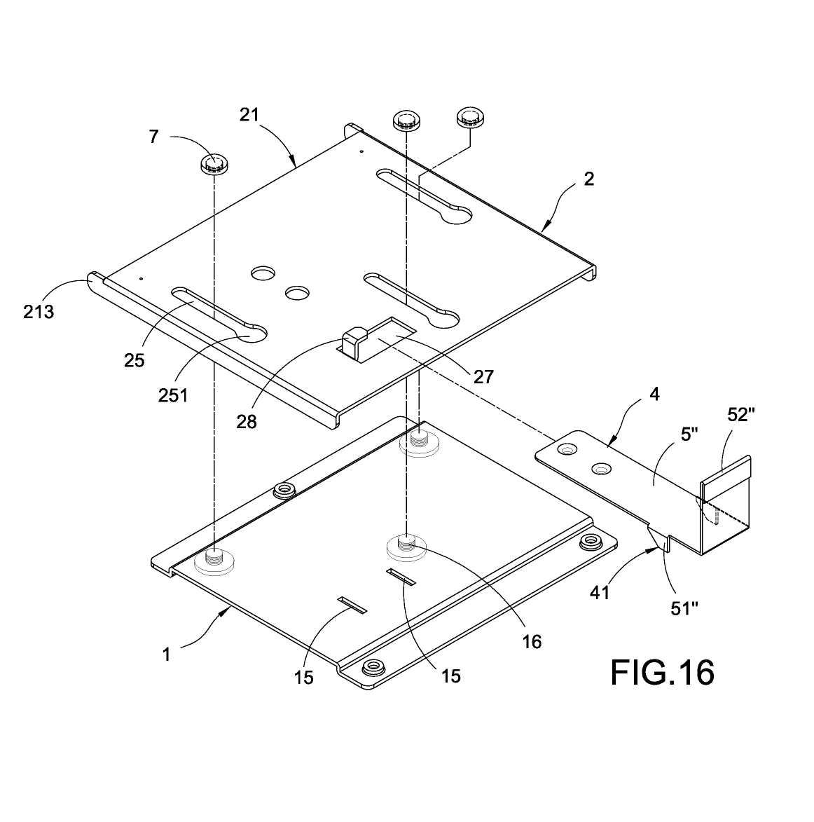

As shown in FIGS. 15 and 16, there are two apertures 15. The sliding seat 2 is provided with a through-opening 27. The locking switch 4 is an elastic arm 5″ fixed to the sliding seat 2. The engaged portion 41 is composed of two bent protrusions 51″ bent at two sides of the elastic arm 5′. The two bent protrusions 51″ are exposed to the through-opening 27 and engaged with the two apertures 15 correspondingly. A toggle piece 52″ extends from one end, away from the detent part 21, of the elastic arm 5″, allowing the vendor or customer to move the sliding seat 2 by means of the toggle piece 52″ to slide with respect to the fastening seat 1. The elastic arm 5″ is fixed to the sliding seat 2 by riveting, but not limited to this.

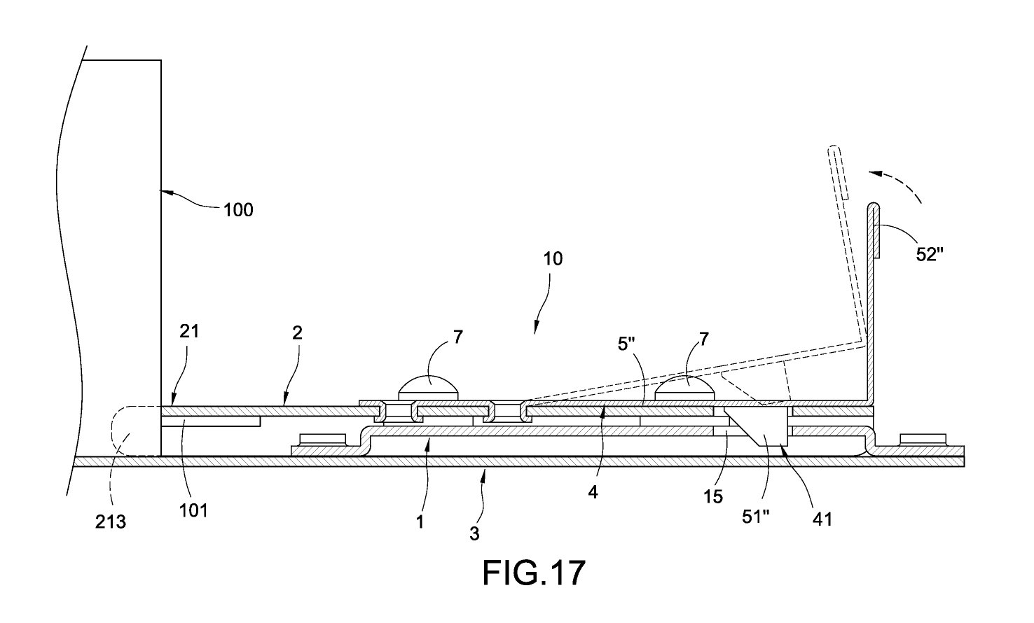

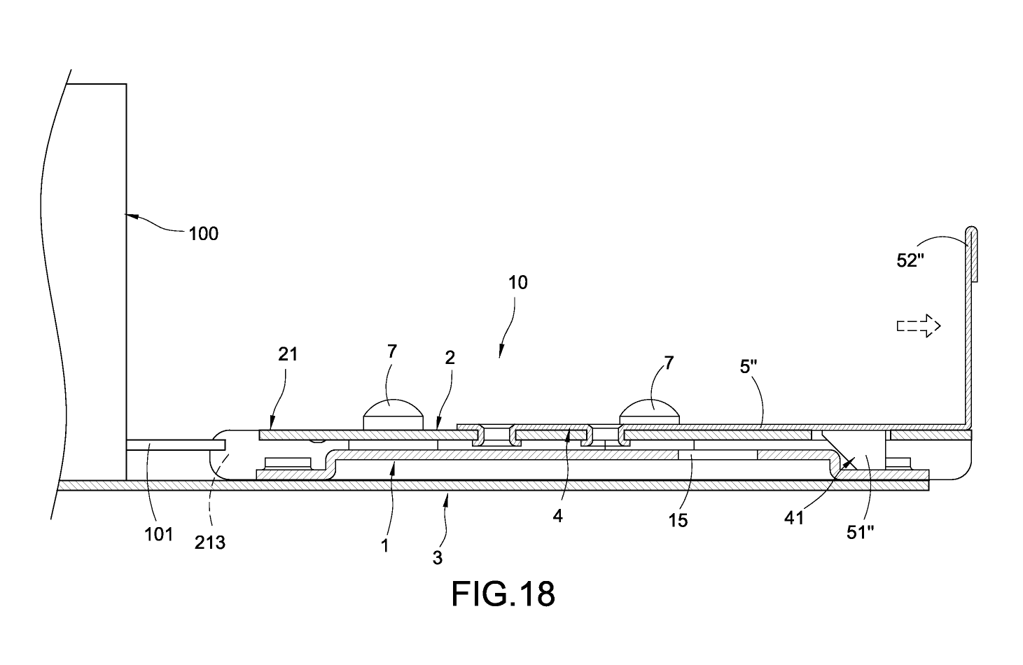

When two bent protrusions 51″ are engaged with two apertures 15 correspondingly, the sliding seat 2 is locked by the locking switch 4 and cannot move, forcing the detent part 21 to keep pressing and locking the positioning plate 101. As shown in FIG. 17, when the elastic arm 5″ is pulled up, it will move the bent protrusions 51″ to be disengaged from the apertures 15. As shown in FIG. 18, after the bent protrusions 51″ are disengaged from the apertures 15, the sliding seat 2 can slide and move the detent part 21 away from the positioning plate 101. In this way, the fourth embodiment achieves the same function and effect as the second embodiment.

Besides, locking switches 4 of various structures can be used in any embodiment of the present invention, depending on the requirement.

Referring to FIGS. 15-17, a stopping piece 28 correspondingly extends from the through-opening 27 on the sliding seat 2. When the elastic arm 5″ deforms too much (i.e., upward excessively), it will be stopped by the stopping piece 28 to prevent an excessive deformation of the elastic arm 5″ to extend the lifetime thereof.

In summary, the securing structure of the electrical peripheral device of the present invention, which has not been revealed in similar products and used in public, is novel, useful, and non-obvious. Please examine the application carefully and grant it as a formal patent for protecting the rights of the inventor.

What is claimed is:

1. A securing structure (10) of an electrical peripheral device (100) having a positioning plate (101), comprising:
a fastening seat (1); and
a sliding seat (2) connected to and sliding on the fastening seat (1), a detent part (21) being disposed at one end of the sliding seat (2), wherein the detent part (21) is able to press and lock the top of the positioning plate (101) correspondingly.

2. The securing structure (10) of an electrical peripheral device (100) according to claim 1, further comprising a supporting frame (3), wherein one end of the supporting frame (3) extends to form a stopping plate (31) and the opposite end of the supporting frame (3) is for securing the fastening seat (1) such that the electrical peripheral device (100) is clamped between the stopping plate (31) and the detent part (21).

3. The securing structure (10) of an electrical peripheral device (100) according to claim 2, wherein the stopping plate (31) has a plurality of projecting pegs (311), wherein the electrical peripheral device (100) is provided with a plurality of locking holes (102) engaged with the corresponding projecting pegs (311).

4. The securing structure (10) of an electrical peripheral device (100) according to claim 1, wherein the fastening seat (1) has a plurality of juts (11), wherein the positioning plate (101) is provided with a plurality of through holes (1011) engaged with the corresponding juts (11).

5. The securing structure (10) of an electrical peripheral device (100) according to claim 1, wherein the sliding seat (2) has a plurality of bulges (26), wherein the positioning plate (101) is provided with a plurality of through holes (1011) engaged with the corresponding bulges (26).

6. The securing structure (10) of an electrical peripheral device (100) according to claim 1, wherein the detent part (21) is a U-shaped portion (211) or an L-shaped portion (212) which extends from the sliding seat (2) toward the positioning plate (101).

7. The securing structure (10) of an electrical peripheral device (100) according to claim 1, wherein the sliding seat (2) is provided with two ribs (213) extending on two ends of the detent part (21), respectively, and the two ribs (213) can be allocated to two ends of the positioning plate (101) to stop the positioning plate (101).

8. The securing structure (10) of an electrical peripheral device (100) according to claim 1, further comprising a locking switch (4) through which the sliding seat (2) and the fastening seat (1) can be positioned to each other.

9. The securing structure (10) of an electrical peripheral device (100) according to claim 8, wherein the locking switch (4) is connected to the fastening seat (1) and has an engaged portion (41), wherein the sliding seat (2) is provided with an engaged hole (22) which can be engaged with the engaged portion (41).

10. The securing structure (10) of an electrical peripheral device (100) according to claim 9, wherein the fastening seat (1) is provided with an opening (12), wherein the locking switch (4) is an elastic arm (5) fixed to the fastening seat (1), wherein the engaged portion (41) is a bent protrusion (51) bent from the elastic arm (5), wherein the bent protrusion (51) is exposed to the opening (12) and engaged with the engaged hole (22) correspondingly.

11. The securing structure (10) of an electrical peripheral device (100) according to claim 8, wherein the locking switch (4) is connected to the sliding seat (2) and has an engaged portion (41), wherein the fastening seat (1) is provided with an aperture (15) with which the engaged portion (41) is engaged correspondingly.

12. The securing structure (10) of an electrical peripheral device (100) according to claim 11, wherein there are a plurality of apertures (15), wherein the sliding seat (2) is provided with an orifice (24), wherein the locking switch (4) is an elastic clasp (6) fixed to the sliding seat (2), wherein the elastic clasp (6) comprises a knob (61), a connecting rod (62), and a spring (63) connected between the knob (61) and the connecting rod (62), wherein the engaged portion (41) is formed at the end of the connecting rod (62), wherein the connecting rod (62) is disposed through the orifice (24) and can be engaged with any of the apertures (15).

13. The securing structure (10) of an electrical peripheral device (100) according to claim 11, wherein there are two apertures (15), wherein the locking switch (4) is an elastic arm (5′) extending from the sliding seat (2), wherein the engaged portion (41) is composed of two bent protrusions (51′) bent at two sides of the elastic arm (5′), wherein the two bent protrusions (51′) can be engaged with the two apertures (15) correspondingly.

14. The securing structure (10) of an electrical peripheral device (100) according to claim 11, wherein there are two apertures (15), wherein the sliding seat (2) is provided with a through-opening (27), wherein the locking switch (4) is an elastic arm (5″) fixed to the sliding seat (2), wherein the engaged portion (41) is composed of two bent protrusions (51″) bent at two sides of the elastic arm (5″), wherein the two bent protrusions (51″) are exposed to the through-opening (27) and engaged with the two apertures (15) correspondingly.

15. The securing structure (10) of an electrical peripheral device (100) according to claim 13 or claim 14, wherein a toggle piece (52′, 52″) extends from one end, away from the detent part 21, of the elastic arm (5′, 5″).

16. The securing structure (10) of an electrical peripheral device (100) according to claim 14, wherein a stopping piece (28) correspondingly extends from the through-opening (27) on the sliding seat (2).

17. The securing structure (10) of an electrical peripheral device (100) according to claim 1, wherein two L-shaped walls (13) extend from the opposites sides of the fastening seat (1), wherein a track (131) is formed between the two L-shaped walls (13), wherein two sides of the sliding seat (2) are received in the two L-shaped walls (13), whereby the sliding seat (2) can slide with respect to the fastening seat (1) by means of the track (131), wherein at least one stopping tab (14) which withstands the sliding seat (2) extends from one end, away from the detent part (21), of the fastening seat (1).

18. The securing structure (10) of an electrical peripheral device (100) according to claim 1, wherein a toggle plate (23) extends from one end, away from the detent part (21), of the sliding seat (2).

19. The securing structure (10) of an electrical peripheral device (100) according to claim 1, further comprising a plurality of screw nuts (7), wherein the fastening seat (1) has a plurality of screw bolts (16), wherein the sliding seat (2) has a plurality of track slots (25), wherein each of the screw bolts (16) penetrates through the corresponding track slots (25) to be screwed to the corresponding screw nuts (7) such that the sliding seat (2) is clamped between the screw bolts (16) and the screw nuts (7), whereby the sliding seat (2) can slide with respect to the fastening seat (1) by means of the track slots (25).

20. The securing structure (10) of an electrical peripheral device (100) according to claim 19, wherein an enlarged hole (251) is disposed at one end of each of the track slots (25), wherein the circumferential size of the enlarged hole (251) is larger than that of the screw nut (7).
